(19) United States
(12) Patent Application Publication
(10) Pub. No.: US 2011/0300702 A1
(43) Pub. Date: Dec. 8, 2011

(54) METHOD FOR FABRICATING SEMICONDUCTOR DEVICE

(75) Inventor: Shunsuke ISONO, Osaka (JP)

(73) Assignee: PANASONIC CORPORATION, Osaka (JP)

(21) Appl. No.: 13/210,983

(22) Filed: Aug. 16, 2011

Related U.S. Application Data
(63) Continuation of application No. PCT/JP2010/000109, filed on Jan. 12, 2010.

(30) Foreign Application Priority Data
Apr. 2, 2009 (JP) 2009-089978

(51) Int. Cl. H01L 21/28

(52) U.S. Cl. 438/592; 438/667; 257/E21.158; 257/E21.19

(57) ABSTRACT

An insulating film is formed on a semiconductor substrate. A metal sacrificial film is formed on the insulating film. Then, the sacrificial film is selectively etched to form a trench pattern in the sacrificial film. The insulating film is irradiated with ultraviolet light or an electron beam using the sacrificial film having the trench pattern as a mask. After that, an interconnect formation groove is formed in the insulating film using the sacrificial film having the trench pattern as a mask. A metal film is formed in the interconnect formation groove.

### CROSS-REFERENCE TO RELATED APPLICATION

This is a continuation of PCT International Application PCT/JP2010/000109 filed on Jan. 12, 2010, which claims priority to Japanese Patent Application No. 2009-089978 filed on Apr. 2, 2009. The disclosures of these applications including the specifications, the drawings, and the claims are hereby incorporated by reference in their entirety.

### BACKGROUND

The present disclosure relates to a method for fabricating a semiconductor device, and specifically relates to a method for fabricating a semiconductor device including a method for forming an interconnect.

In recent years, miniaturization and higher integration of semiconductor integrated circuits are making significant progress. However, although it becomes possible to reduce a delay time of a transistor with the miniaturization of the semiconductor integrated circuits, it becomes difficult to reduce a delay time of an interconnect due to an increase in interconnect resistance and parasitic capacitance.

In view of this, as a measure of reducing the interconnect resistance, aluminum (Al) which is conventionally used as a material for the interconnect is replaced with copper (Cu) having a resistance lower than a resistance of aluminum. Further, as a measure of reducing the parasitic capacitance, an interlayer insulating film whose dielectric constant is lower than a dielectric constant of silicon dioxide (SiO₂), that is, a low dielectric constant interlayer insulating film, is used. Since copper is not easily etched, a technique in which a trench pattern is formed in the interlayer insulating film by an inlay or damascene technique, and the trench pattern is filled with copper, is used.

However, as the dielectric constant of the interlayer insulating film becomes low, the strength of the interlayer insulating film is lowered. For this reason, a low dielectric constant interlayer insulating film may not be able to endure stress applied during chemical mechanical polishing (CMP), interconnect bonding, and packaging. Thus, as shown in Japanese Patent Publication No. 2006-165573, a technique in which the strength of the low dielectric constant interlayer insulating film is increased by irradiation with an electron beam or ultraviolet light is also suggested.

### SUMMARY

However, the above conventional method for fabricating a semiconductor device has a problem that a relative dielectric constant of the interlayer insulating film will be increased by the irradiation of the interlayer insulating film with an electron beam or ultraviolet light. This is because there is a trade-off relationship between an increase in strength of the low dielectric constant film due to irradiation with an electron beam or ultraviolet light, and a reduction in relative dielectric constant.

The present invention was made to solve the above problem, and it is an objective of the present invention to simultaneously achieve an increase in strength of an interconnect structure, and a reduction in dielectric constant of an interlayer insulating film.

To achieve the above objective, a method for fabricating a semiconductor device according to the present invention includes increasing the strength of an interlayer insulating film made of a low dielectric constant film, selectively at a region where an interconnect or a contact plug is formed.

Specifically, a method for fabricating a first semiconductor device according to the present invention includes: forming an insulating film on a semiconductor substrate; forming a metal sacrificial film on the insulating film; selectively etching the sacrificial film to form an opening pattern in the sacrificial film; irradiating the insulating film with ultraviolet light or an electron beam using the sacrificial film having the opening pattern as a mask; after the irradiating, forming a hole or a groove in the insulating film using the sacrificial film having the opening pattern as a mask; and forming a conductive film in the hole or the groove.

According to the method for fabricating the first semiconductor device, the insulating film is irradiated with ultraviolet light or an electron beam using the metal sacrificial film having the opening pattern as a mask. Thus, the insulating film can be selectively cured only at a region where a hole or a groove is formed and strength is necessary. On the other hand, a space between the regions where a hole or a groove is formed, the space affecting the performance of the semiconductor device, is not cured. Thus, the relative dielectric constant of the insulating film is not increased. As a result, the interconnect capacitance is not increased, and the performance of the semiconductor device is not degraded.

In the method for fabricating the first semiconductor device, the conductive film may be made of a metal.

In the method for fabricating the first semiconductor device, the insulating film may be a single layer film having silicon and oxygen as main components, and containing at least one of carbon or nitrogen in a composition, or a multilayer film including at least one layer of the single layer film.

A method for fabricating a second semiconductor device according to the present invention includes: forming a first insulating film on a semiconductor substrate; forming an interconnect in an upper portion of the first insulating film; forming a second insulating film on the first insulating film including the interconnect; forming a metal sacrificial film on the second insulating film; selectively etching the sacrificial film to form an opening pattern in the sacrificial film; irradiating the second insulating film with ultraviolet light or an electron beam using the sacrificial film having the opening pattern as a mask; after the irradiating, forming a hole or a groove in the second insulating film using the sacrificial film having the opening pattern as a mask; and forming a conductive film in the hole or the groove.

According to the method for fabricating the second semiconductor device, the second insulating film is irradiated with ultraviolet light or an electron beam using the metal sacrificial film having the opening pattern as a mask. Thus, the second insulating film can be selectively cured only at a region where a hole or a groove is formed and strength is necessary. On the other hand, a space between the regions where a hole or a groove is formed, the space affecting the performance of the semiconductor device, is not cured. Thus, the relative dielectric constant of the second insulating film is not increased. As a result, the interconnect capacitance is not increased, and the performance of the semiconductor device is not degraded.

In the method for fabricating the second semiconductor device, at least one of the interconnect or the conductive film may be made of a metal.

In the method for fabricating the second semiconductor device, the second insulating film may be a single layer film having silicon and oxygen as main components, and containing at least one of carbon or nitrogen in a composition, or a multilayer film including at least one layer of the single layer film.

In the method for fabricating the first semiconductor device or the second semiconductor device, the sacrificial film may be made of titanium, titanium nitride, tantalum, or tantalum nitride.

In the method for fabricating the second semiconductor device, in the selective etching, the opening pattern may be formed in the sacrificial film at a location above the interconnect.

According to a method for fabricating a semiconductor device of the present invention, it is possible to simultaneously achieve an increase in strength of an interconnect structure, and a reduction in dielectric constant of an interlayer insulating film.

### BRIEF DESCRIPTION OF THE DRAWINGS

FIG. 1A to FIG. 1F are cross-sectional views for illustrating steps of a method for fabricating a semiconductor device according to the first embodiment of the present invention.

FIG. 2A to FIG. 2F are cross-sectional views for illustrating steps of a method for fabricating a semiconductor device according to the second embodiment of the present invention.

FIG. 3 shows a film strength distribution of an interlayer insulating film according to a method for fabricating a semiconductor device according to the second embodiment of the present invention.

### DETAILED DESCRIPTION

### First Embodiment

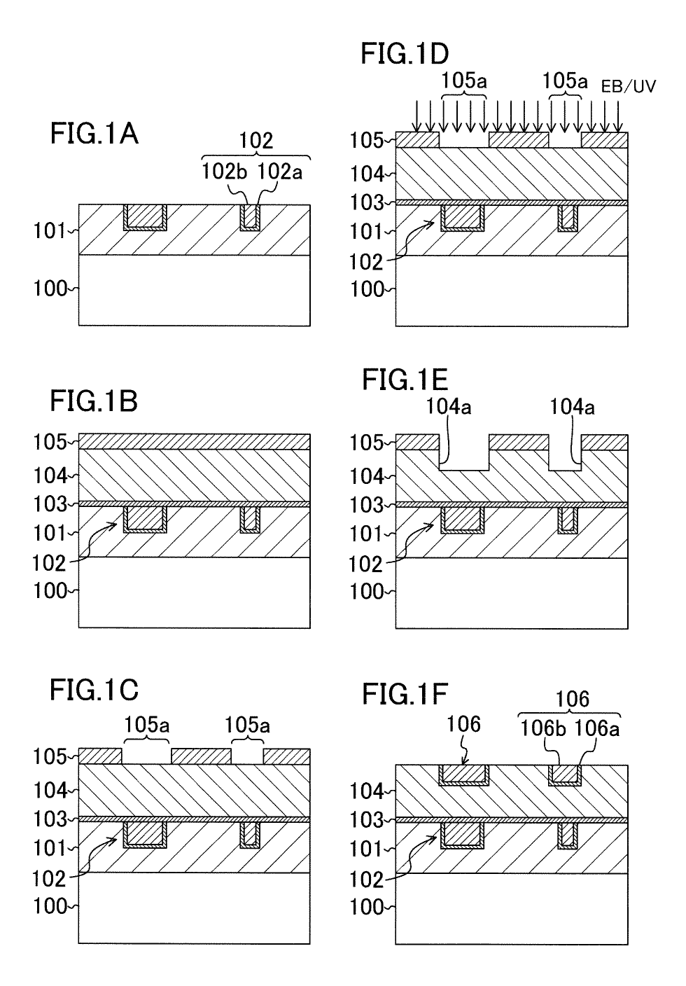

A method for fabricating a semiconductor device according to the first embodiment of the present invention will be described with reference to FIG. 1. The materials and numerical values used in the present disclosure are merely a preferable example, and the present disclosure is not limited to this embodiment. The embodiment can be practiced with modification and alteration within the spirit and scope of the present disclosure. Moreover, if necessary, the present embodiment can be combined with the second embodiment.

First, as shown in FIG. 1A, a first insulating film 101 made of a silicon dioxide (SiO₂) having a thickness of about 300 nm is formed on a silicon (Si) semiconductor substrate 100 by chemical vapor deposition (CVD), for example. Then, a first resist pattern (not shown) having a first metal interconnect pattern (a first trench (groove) pattern) is formed on the first insulating film 101 by lithography. After that, the first insulating film 101 is dry etched using the first resist pattern as a mask, thereby forming a plurality of first interconnect formation grooves in an upper portion of the first insulating film 101. Then, the first resist pattern is removed by ashing. A first barrier metal film 102a formed by layering tantalum nitride (TaN) and tantalum (Ta), and a first metal film 102b made of copper (Cu) are sequentially formed on the first insulating film 101 by CVD or sputtering to fill in the first interconnect formation grooves. After that, the unwanted portions of the first metal film 102b and the first barrier metal film 102a which are formed on the upper surface of the first insulating film 101 are polished by chemical mechanical polishing (CMP), thereby forming a first metal interconnect 102 including the first barrier metal film 102a and the first metal film 102b.

Next, as shown in FIG. 1B, a second insulating film 103 made of silicon carbon nitride (SiCN) having a thickness of about 30 nm is formed by CVD on the entire first insulating film 101 including the first metal interconnect 102. Then, a third insulating film 104 made of carbon doped silicon oxide (SiOC) having a thickness of about 300 nm is formed on the second insulating film 103. Here, the third insulating film 104 may be made of nitrogen doped silicon oxide (SiON) in place of SiOC.

Then, a sacrificial film 105 made of titanium (Ti) or titanium nitride (TiN) having a thickness of about 30 nm is formed on the third insulating film 104 by CVD or sputtering. The sacrificial film 105 may be made of tantalum (Ta) or tantalum nitride (TaN), etc., in place of Ti and TiN. The second insulating film 103 is not necessarily provided.

Next, as shown in FIG. 1C, a second resist pattern (not shown) having a second metal interconnect pattern (a second trench pattern) is formed on the sacrificial film 105 by lithography. The sacrificial film 105 is dry etched using the second resist pattern as a mask. Then, the second resist pattern is removed by ashing, and a residue of the resist at the etching (e.g., a polymer) is removed by wet etching to form a second trench pattern 105a in the sacrificial film 105.

Then, as shown in FIG. 1D, the third insulating film 104 is irradiated with at least one of an electron beam (EB) or ultraviolet light (UV) using the sacrificial film 105 having the second trench pattern 105a as a mask, thereby curing only a region of the third insulating film 104 at which the second trench pattern is formed.

Next, as shown in FIG. 1E, the third insulating film 104 is dry etched using the sacrificial film 105 as a mask, thereby forming a plurality of second interconnect formation grooves 104a in an upper portion of the third insulating film 104.

Next, as shown in FIG. 1F, the sacrificial film 105 is removed by dry etching, and then, a second barrier metal film 106a formed by layering tantalum nitride (TaN) and tantalum (Ta), and a second metal film 106b made of copper (Cu) are sequentially formed on the third insulating film 104 by CVD or sputtering to fill in the second interconnect formation grooves 104a. After that, the unwanted portions of the metal film and the barrier metal film which are formed on the upper surface of the third insulating film 104 are polished by CMP, thereby forming a second metal interconnect 106 including the second barrier metal film 106a and the second metal film 106b.

As described above, according to the first embodiment, the third insulating film 104 made of silicon oxycarbide is selectively cured only at a region where the second trench pattern 105a is formed. As a result, the strength of the third insulating film 104 is increased only at a region where the second trench pattern 105a is formed. On the other hand, a region of the third insulating film 104 in which the second trench pattern 105a is not formed and which affects the performance of the semiconductor device, is not cured. Thus, the relative dielectric constant of the uncured region is not increased. As a result, the interconnect capacitance is not increased, and the performance of the semiconductor device is not degraded. Here, the region where the second trench pattern 105a is formed does not only refer to a region directly under the second trench pattern 105a, but also includes a region adjacent to the region directly under the second trench pattern 105a. When the third insulating film 104 is irradiated with at least one of an electron beam (EB) or ultraviolet light (UV), the electron beam or the ultraviolet light is dispersed in the third insulating film 104, and thus, the region adjacent to the region directly under the second trench pattern 105a is also cured. Here, the term “adjacent” refers to a distance within which the electron beam or the ultraviolet light can be dispersed. Since this distance is short, the effect on an increase in interconnect capacitance is very small.

In the case where ultraviolet light is used to selectively cure the third insulating film 104, a region of the third insulating film 104 in which the second trench patterns 105a are densely formed to obtain interconnects having a width of about 200 nm or less can be efficiently cured by using ultraviolet light in a wavelength band of about 200 nm to about 400 nm, due to a diffraction effect from each interconnect.

The interconnect bodies of the first metal interconnect 102 and the second metal interconnect 106 excluding the barrier metal films 102a, 106a are preferably made of a metal, more preferably made of copper. However, the interconnect bodies according to the present embodiment are not necessarily limited to a metal.

### Second Embodiment

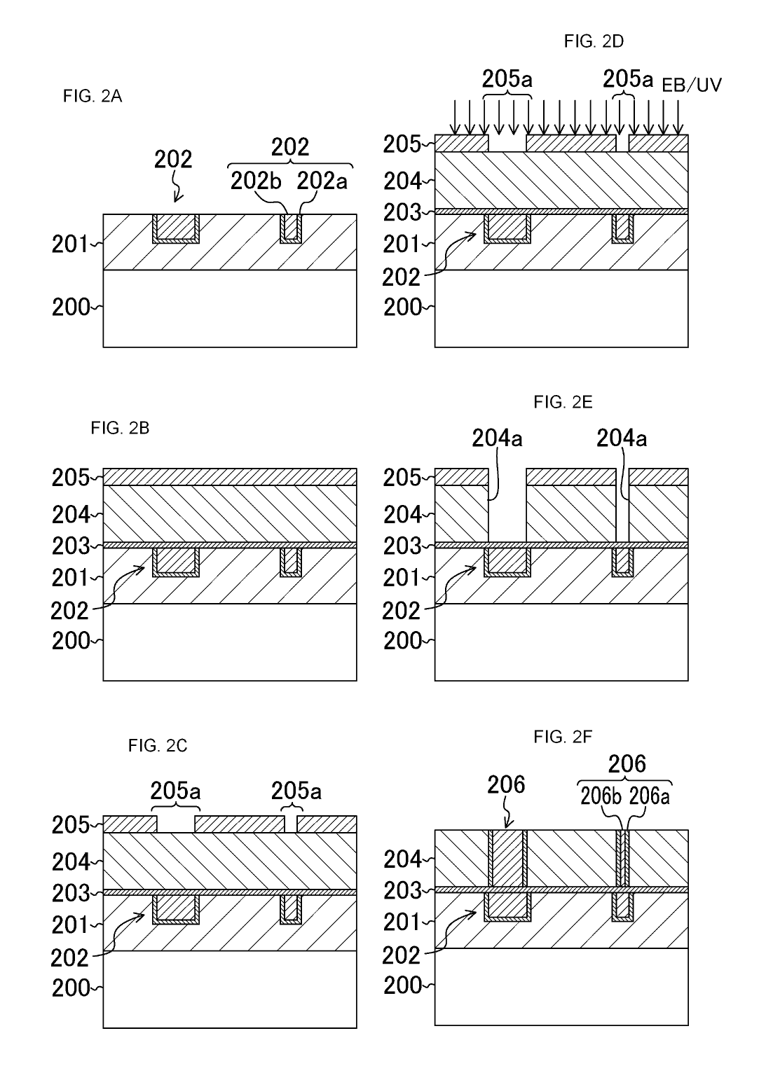

A method for fabricating a semiconductor device according to the second embodiment of the present invention will be described below with reference to FIG. 2.

First, as shown in FIG. 2A, a first insulating film 201 made of a silicon dioxide (SiO₂) having a thickness of about 300 nm is formed on a silicon (Si) semiconductor substrate 200 by CVD, for example. Then, a first resist pattern (not shown) having a metal interconnect pattern (a trench pattern) is formed on the first insulating film 201 by lithography. After that, the first insulating film 201 is dry etched using the first resist pattern as a mask, thereby forming a plurality of first interconnect formation grooves in an upper portion of the first insulating film 201. Then, the first resist pattern is removed by ashing. A first barrier metal film 202a formed by layering tantalum nitride (TaN) and tantalum (Ta), and a first metal film 202b made of copper (Cu) are sequentially formed on the first insulating film 201 by CVD or sputtering to fill in the first interconnect formation grooves. After that, the unwanted portions of the first metal film 202b and the first barrier metal film 202a which are formed on the upper surface of the first insulating film 201 are polished by CMP, thereby forming a metal interconnect 202 including the first barrier metal film 202a and the first metal film 202b.

Next, as shown in FIG. 2B, a second insulating film 203 made of silicon carbon nitride (SiCN) having a thickness of about 30 nm is formed by CVD on the entire first insulating film 201 including the first metal interconnect 202. Then, a third insulating film 204 made of carbon doped silicon oxide (SiOC) having a thickness of about 300 nm is formed on the second insulating film 203. Here, the third insulating film 204 may be made of nitrogen doped silicon oxide (SiON) in place of SiOC. After that, a sacrificial film 205 made of titanium (Ti) or titanium nitride (TiN) having a thickness of about 30 nm is formed on the third insulating film 204 by CVD or sputtering. The sacrificial film 205 may be made of tantalum (Ta) or tantalum nitride (TaN), etc., in place of Ti and TiN.

Next, as shown in FIG. 2C, a second resist pattern (not shown) having a hole pattern is formed on the sacrificial film 205 by lithography. The sacrificial film 205 is dry etched using the second resist pattern as a mask. Then, the second resist pattern is removed by ashing, and a residue of the resist at the etching (e.g., a polymer) is removed by wet etching to form a hole pattern 205a in the sacrificial film 205.

Then, as shown in FIG. 2D, the third insulating film 204 is irradiated with at least one of an electron beam (EB) or ultraviolet light (UV) using the sacrificial film 205 as a mask, thereby curing only a region of the third insulating film 204 at which the hole pattern is formed.

Next, as shown in FIG. 2E, the third insulating film 204 is dry etched using the sacrificial film 205 as a mask, thereby forming a plurality of contact holes 204a in an upper portion of the third insulating film 204.

Next, as shown in FIG. 2F, the sacrificial film 205 is removed by dry etching, and then, a second barrier metal film 206a formed by layering tantalum nitride (TaN) and tantalum (Ta), and a second metal film 206b made of copper (Cu) or tungsten (W) are sequentially formed on the third insulating film 204 by CVD or sputtering to fill in the contact holes 204a. After that, the unwanted portions of the second metal film 206b and the second barrier metal film 206a formed on the upper surface of the third insulating film 204 are polished by CMP, thereby forming a contact plug 206 including the second barrier metal film 206a and the second metal film 206b.

As described above, according to the second embodiment, the third insulating film 204 made of silicon oxycarbide is selectively cured only at a region where the hole pattern 205a is formed. As a result, the strength of the third insulating film 204 is increased only at the region where the hole pattern 205a is formed. On the other hand, a region of the third insulating film 204 other than the region where the hole pattern 205a is formed which affects the performance of the semiconductor device, is not cured. Thus, the relative dielectric constant of the uncured region is not increased. As a result, the interconnect capacitance is not increased, and the performance of the semiconductor device is not degraded. Here, the region where the hole pattern 205a is formed does not only refer to a region directly under the hole pattern 205a, but also includes a region adjacent to the region directly under the hole pattern 205a. When the third insulating film 204 is irradiated with at least one of an electron beam (EB) or ultraviolet light (UV), the electron beam or the ultraviolet light is dispersed in the third insulating film 204, and thus, the region adjacent to the region directly under the hole pattern 205a is also cured. Here, the term “adjacent” refers to a distance within which the electron beam or the ultraviolet light can be dispersed.

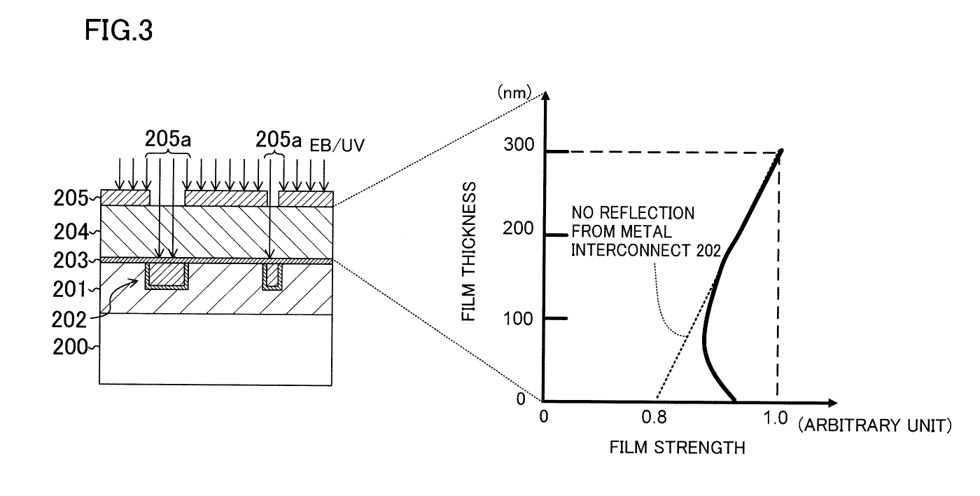

Further, as shown in FIG. 3, the electron beam or the ultraviolet light is reflected by the metal interconnect 202. Thus, the strength of a lower portion of the contact hole 204a which significantly affects the reliability of the through hole, can be further increased. Accordingly, the reliability of the contact plug 206 (stress-migration registance and electro-migration registance) can be improved. Here, the broken line in FIG. 3 indicates a relationship between the film thickness and the film strength in the case where the electron beam or the ultraviolet light is not emitted and therefore not reflected by the metal interconnect 202. The solid line indicates a relationship between the film thickness and the film strength in the case where the electron beam or the ultraviolet light is emitted and therefore reflected by the metal interconnect 202.

In the case where ultraviolet light is used to selectively cure the third insulating film 204, a region of the third insulating film 204 in which the hole patterns 205a are densely formed to obtain interconnects having a width of about 200 nm or less can be efficiently cured by using ultraviolet light in a wavelength band of about 200 nm to about 400 nm, due to a diffraction effect from each interconnect.

The interconnect body of the metal interconnect 202 excluding the first barrier metal film 202a is preferably made of a metal, more preferably made of copper. However, the interconnect body according to the present embodiment is not necessarily limited to a metal.

According to a method for fabricating a semiconductor device of the present invention, it is possible to simultaneously achieve an increase in strength of an interconnect structure, and a reduction in dielectric constant of an interlayer insulating film, and the method is useful as a method for fabricating a semiconductor device, etc., including a method for forming an interconnect.

What is claimed is:

1. A method for fabricating a semiconductor device, comprising:
forming an insulating film on a semiconductor substrate;
forming a metal sacrificial film on the insulating film;
selectively etching the sacrificial film to form an opening pattern in the sacrificial film;
irradiating the insulating film with ultraviolet light or an electron beam using the sacrificial film having the opening pattern as a mask;
after the irradiating, forming a hole or a groove in the insulating film using the sacrificial film having the opening pattern as a mask; and
forming a conductive film in the hole or the groove.

2. The method of claim 1, wherein
the conductive film is made of a metal.

3. The method of claim 1, wherein
the insulating film is a single layer film having silicon and oxygen as main components, and containing at least one of carbon or nitrogen in a composition, or a multilayer film including at least one layer of the single layer film.

4. The method of claim 1, wherein
the sacrificial film is made of titanium, titanium nitride, tantalum, or tantalum nitride.

5. A method for fabricating a semiconductor device, comprising:
forming a first insulating film on a semiconductor substrate;
forming an interconnect in an upper portion of the first insulating film;
forming a second insulating film on the first insulating film including the interconnect;
forming a metal sacrificial film on the second insulating film;
selectively etching the sacrificial film to form an opening pattern in the sacrificial film;
irradiating the second insulating film with ultraviolet light or an electron beam using the sacrificial film having the opening pattern as a mask;
after the irradiating, forming a hole or a groove in the second insulating film using the sacrificial film having the opening pattern as a mask; and
forming a conductive film in the hole or the groove.

6. The method of claim 5, wherein
at least one of the interconnect or the conductive film is made of a metal.

7. The method of claim 5, wherein
the second insulating film is a single layer film having silicon and oxygen as main components, and containing at least one of carbon or nitrogen in a composition, or a multilayer film including at least one layer of the single layer film.

8. The method of claim 5, wherein
the sacrificial film is made of titanium, titanium nitride, tantalum, or tantalum nitride.

9. The method of claim 5, wherein
in the selective etching, the opening pattern is formed in the sacrificial film at a location above the interconnect.
